(19) United States
(12) Patent Application Publication
(10) Pub. No.: US 2023/0230899 A1
(43) Pub. Date: Jul. 20, 2023

(54) SEMICONDUCTOR APPARATUS

(71) Applicant: FUJI ELECTRIC CO., LTD., Kawasaki-shi (JP)

(72) Inventors: Ginji UCHIBE, Tokyo (JP); Yasutaka SANUKI, Sagamihara-city (JP); Jun NAKAMURA, Tokyo (JP)

(73) Assignee: FUJI ELECTRIC CO., LTD., Kawasaki-shi (JP)

(21) Appl. No.: 18/070,943

(22) Filed: Nov. 29, 2022

(30) Foreign Application Priority Data
Jan. 19, 2022 (JP) 2022-006376

(51) Int. Cl. H01L 23/473; H01L 23/40

(52) U.S. Cl. CPC H01L 23/473; H01L 23/40

(57) ABSTRACT

A semiconductor apparatus includes: a semiconductor module; a cooler including flow paths through which a refrigerant flows; a casing including a bottom surface; at least one first fixing member fixing the cooler to the bottom surface; and at least one second fixing member fixing the cooler to the bottom surface. The cooler includes: an outer surface directed to the bottom surface of the casing; an inner surface that is a part of wall surfaces of the flow paths on an opposite side to the outer surface; an outer wall to which the at least one first fixing member is connected; and an outer wall that is on an opposite side to the outer wall and to which the at least one second fixing member is connected. The semiconductor module is positioned between the bottom surface of the casing and the outer surface of the cooler, and is pressed by these two surfaces.

### CROSS REFERENCE TO RELATED APPLICATION

This Application claims priority from Japanese Patent Application No. 2022-6376, filed Jan. 19, 2022, the entire contents of which are incorporated herein by reference.

### BACKGROUND

### Field of the Invention

The present invention relates to semiconductor apparatuses.

### Description of Related Art

A method is known in which a semiconductor apparatus, including a heat generating device such as a switching element, is cooled by a refrigerant such as cooling water. For example, Japanese Patent Application Laid-Open Publication No. 2020-073845 discloses that a heat transfer plate thermally coupled to a heat generating device is cooled using a cooling fluid to cool a heat generating device. Japanese Patent Application Laid-Open Publication No. 2007-329167 discloses a semiconductor apparatus in which a semiconductor module arranged on the upper surface of a heatsink is fixed by a plate spring arranged on the upper surface of the semiconductor module.

### SUMMARY

Reduction in the number of parts is desired for the semiconductor apparatus as described above. In view of the above circumstances, one aspect of the present invention is aimed at reducing the number of parts.

A semiconductor apparatus according to a preferred embodiment of the present invention includes: a semiconductor module; a cooler including flow paths through which a refrigerant flows; a support including an installation surface; at least one first fixing member fixing the cooler to the installation surface; and at least one second fixing member fixing the cooler to the installation surface, in which: the cooler includes: a first surface directed to the installation surface; a second surface that is a part of wall surfaces of the flow paths on an opposite side to the first surface; a first sidewall to which the at least one first fixing member is connected; and a second sidewall that is on an opposite side to the first sidewall and to which the at least one second fixing member is connected, and the semiconductor module is positioned between the installation surface and the first surface, and is pressed by the installation surface and the first surface.

### BRIEF DESCRIPTION OF THE DRAWINGS

FIG. 1 is an exploded perspective view schematically illustrating relevant parts of a power converter according to an embodiment;

FIG. 2 is an explanatory diagram for explaining a head portion illustrated in FIG. 1;

FIG. 3 is an explanatory diagram for explaining a main body illustrated in FIG. 1;

FIG. 4 is a cross-sectional view of the power converter along a line B1-B2 illustrated in a first plan view of FIG. 2;

FIG. 5 is an explanatory diagram for explaining an example of a power converter according to a comparative example;

FIG. 6 is a perspective view illustrating an example of a schematic internal structure of the entire power converter;

FIG. 7 is an explanatory diagram for explaining an example of a power converter according to a first modification; and

FIG. 8 is an explanatory diagram for explaining an example of a cooler according to a second modification.

### DESCRIPTION OF THE EMBODIMENT

An embodiment according to the present invention is explained with reference to the drawings. The dimensions and scales of parts in the drawings may differ from actual products as appropriate. The embodiment described below is a preferable specific example of the present invention.

Therefore, the following embodiments include various technically preferable limitations. However, the scope of the present invention is not limited to the embodiment unless it is so stated in the following explanations that the present invention is specifically limited.

### A. Embodiment

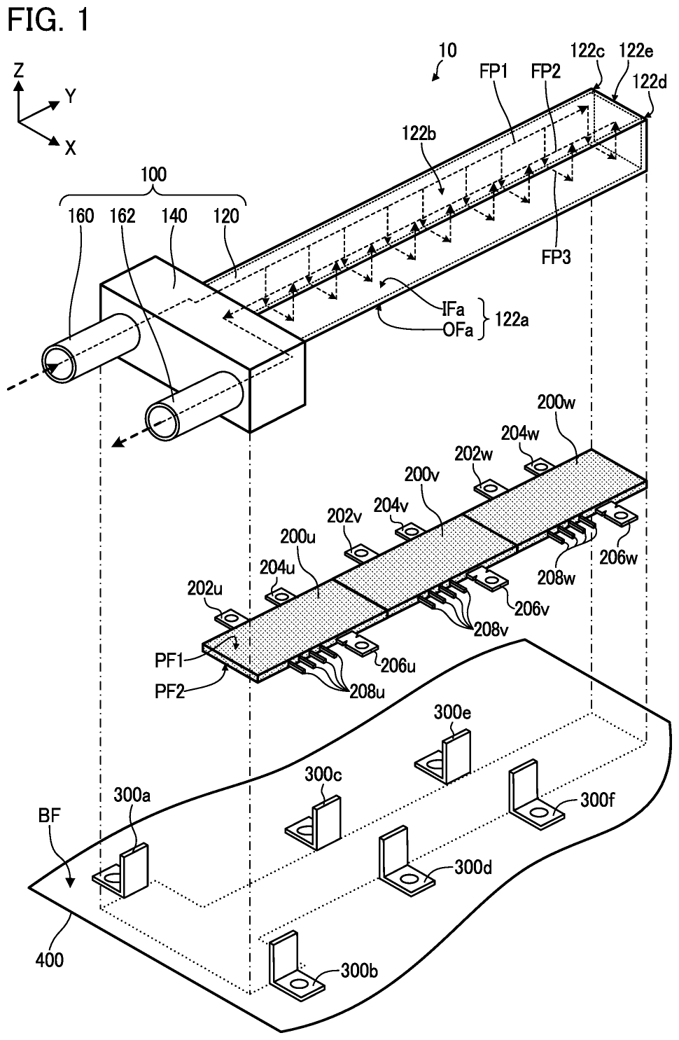

An embodiment of the present invention is explained below. An example of the outline of a power converter 10 according to this embodiment is explained first with reference to FIG. 1.

FIG. 1 is an exploded perspective view schematically illustrating relevant parts of the power converter 10 according to the embodiment.

A rectangular coordinate system with three axes including an X-axis, a Y-axis, and a Z-axis perpendicular to each other is hereinafter adopted for the purpose of illustration. Hereinafter, the direction indicated by the arrow of the X-axis is referred to as “+X direction” and the direction opposite to the +X direction is referred to as “−X direction.” The direction indicated by the arrow of the Y-axis is referred to as “+Y direction” and the direction opposite to the +Y direction is referred to as “−Y direction.” The direction indicated by the arrow of the Z-axis is referred to as “+Z direction” and the direction opposite to the +Z direction is referred to as “−Z direction.” Hereinafter, the +Y direction and the −Y direction are sometimes referred to as the “Y direction” without distinction, the +X direction and the −X direction are sometimes referred to as the “X direction” without distinction. The +Z direction and the −Z direction are sometimes referred to as the “Z direction” without distinction.

Each of the +Y direction and the −Y direction is an example of a “first direction,” each of the +X direction and the −X direction is an example of a “second direction,” and each of the +Z direction and the −Z direction is an example of a “third direction.” Hereinafter, viewing an object from a certain direction is sometimes referred to as a “plan view.”

Examples of the power converter 10 include an inverter and a converter. The power converter 10 is an example of a “semiconductor apparatus.” In this embodiment, a power semiconductor apparatus that converts DC power input to the power converter 10 to AC power of three phases including a U phase, a V phase, and a W phase is assumed as the power converter 10.

In one example, the power converter 10 has three semiconductor modules 200u, 200v, and 200w that convert DC power to AC power, a cooler 100, a plurality of fixing members 300a, 300b, 300c, 300d, 300e, and 300f, and a casing 400. In FIG. 1, a part (a bottom surface BF) of the casing 400 is illustrated. The casing 400 is an example of a “support,” and the bottom surface BF of the casing 400 is an example of an “installation surface.” Each of the fixing members 300c and 300e is an example of a “first fixing member,” and each of the fixing members 300d and 300f is an example of a “second fixing member.”

Hereinafter, the fixing members 300a, 300b, 300c, 300d, 300e, and 300f are simply referred to as “fixing members 300.” Although the six fixing members 300 are illustrated in FIG. 1, the number of the fixing members 300 may be less than six, or it may be seven or more.

Each of the semiconductor modules 200u, 200v, and 200w is a power semiconductor module that has a power semiconductor chip including a power semiconductor element such as a switching element accommodated in a resin case. Examples of the switching element include a power MOSFET (Metal Oxide Semiconductor Field Effect Transistor) and an IGBT (Insulated Gate Bipolar Transistor).

The semiconductor module 200u has input terminals 202u and 204u, an output terminal 206u, and a plurality of control terminals 208u. In one example, the semiconductor module 200u converts DC power input to the input terminals 202u and 204u into U-phase AC power of the three-phase AC power, and outputs the U-phase AC power from the output terminal 206u. The potential of the input terminal 202u is higher than that of the input terminal 204u. Control signals for controlling an operation of a switching element and the like included in the semiconductor module 200u are input to the control terminals 208u, respectively.

Each of the semiconductor modules 200v and 200w is substantially the same as the semiconductor module 200u except for outputting the V-phase or W-phase AC power of the three-phase AC power. In one example, the semiconductor module 200v has input terminals 202v and 204v, an output terminal 206v, and a plurality of control terminals 208v, and outputs the V-phase AC power from the output terminal 206v. In one example, the semiconductor module 200w has input terminals 202w and 204w, an output terminal 206w, and a plurality of control terminals 208w, and outputs the W-phase AC power from the output terminal 206w.

Hereinafter, the semiconductor modules 200u, 200v, and 200w are simply referred to as “semiconductor module 200.” The input terminals 202u, 202v, and 202w are simply referred to as “input terminal 202,” the input terminals 204u, 204v, and 204w are simply referred to as “input terminal 204,” and the output terminals 206u, 206v, and 206w are simply referred to as “output terminal 206.” In this embodiment, a surface directed to the bottom surface BF of the casing 400 among the surfaces of the semiconductor module 200 is referred to as “surface PF2,” and the opposite surface to the surface

PF2 is referred to as “surface PF1.”

The cooler 100 cools the semiconductor module 200 using a refrigerant. The cooler 100 has a main body 120 extending in the Y direction, a supply pipe 160 that supplies the refrigerant to the main body 120, a discharge pipe 162 that discharges the refrigerant from the main body 120, and a head portion 140 that connects the supply pipe 160 and the discharge pipe 162 to the main body 120. Dashed arrows in FIG. 1 indicate an example of the flow of the refrigerant. In this embodiment, the refrigerant is a liquid such as water.

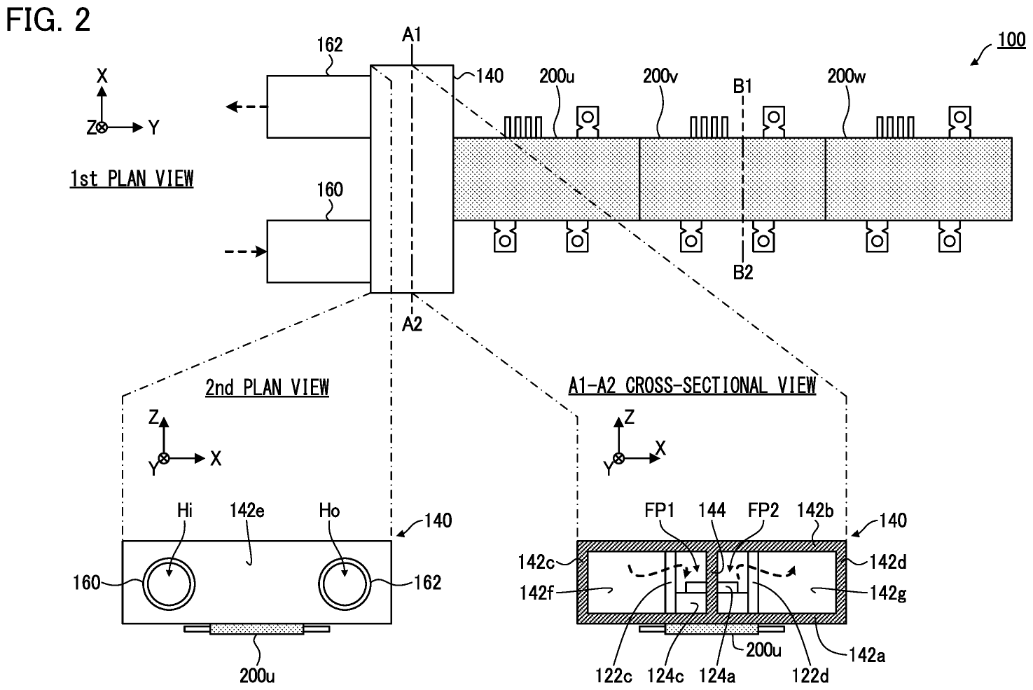

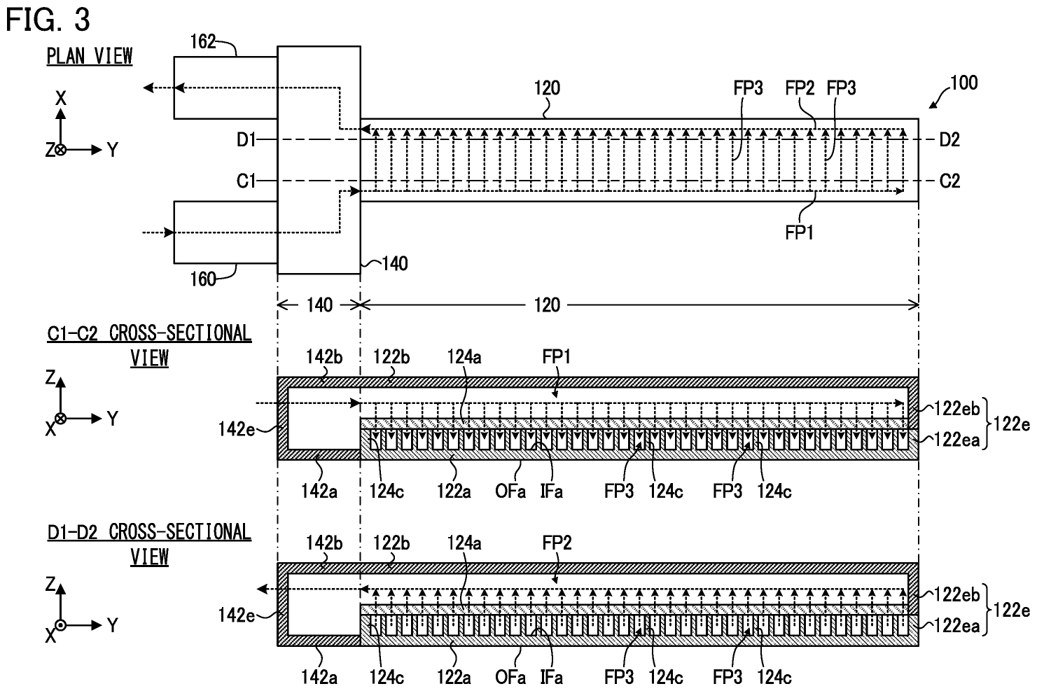

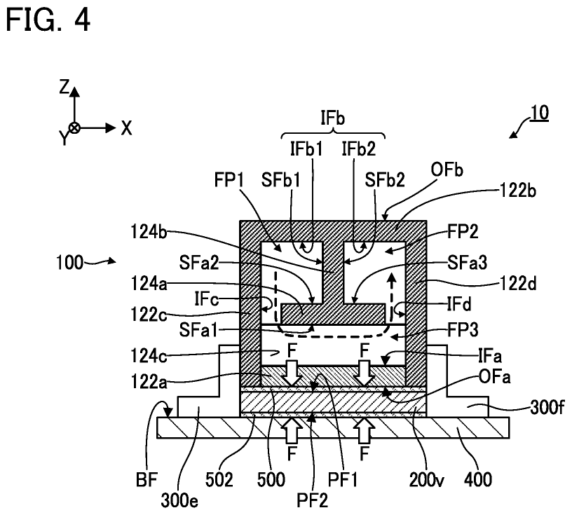

FIG. 1 illustrates the outline of the main body 120. Details of the main body 120 are explained with reference to FIGS. 3 and 4 described later. The head portion 140 is explained with reference to FIG. 2 described later.

In one example, the main body 120 is a hollow structure formed into a cuboid extending in the Y direction, and has outer walls 122a, 122b, 122c, 122d, and 122e. Hereinafter, the outer walls 122a, 122b, 122c, 122d, and 122e are simply referred to as “outer wall 122.” Flow paths through which the refrigerant flows are formed in a space defined by the outer wall 122.

In this embodiment, a case is given in which an inflow path FP1 extending in the Y direction and having an end into which the refrigerant flows, an outflow path FP2 extending in the Y direction and having from which the refrigerant flows out, and flow paths FP3 arrayed in the Y direction and extending in the X direction are provided as the flow paths in the main body 120. The other end (an end portion in the +Y direction) of each of the inflow path FP1 and the outflow path FP2 is defined by the outer wall 122e. One end and the other end of each of the cooling flow paths FP3 are defined by the outer walls 122c and 122d, respectively. The inflow path FP1 is an example of a “first flow path,” and the outflow path FP2 is an example of a “second flow path.”

The outer wall 122a includes an outer surface OFa directed to the bottom surface BF of the casing 400, and an inner surface IFa constituting a part of the wall surfaces of the flow paths on the opposite side to the outer surface OFa. In one example, the inner surface IFa of the outer wall 122a is a part of wall surfaces of the cooling flow paths FP3. The outer surface OFa is an example of a “first surface,” and the inner surface IFa is an example of a “second surface.” Hereinafter, the outer surface OFa of the outer wall 122a is referred to as “outer surface OFa of the cooler 100.”

The outer walls 122c and 122d are sidewalls substantially perpendicular to the outer wall 122a. Descriptions such as “substantially perpendicular” and “substantially parallel”, which will be described later, indicate concepts including an error. It suffices that a state “substantially perpendicular” is a state perpendicular in design. The outer wall 122c is an example of a “first sidewall.” The fixing members 300c and 300e are connected to the outer wall 122c. The outer wall 122d is a sidewall on the opposite side to the outer wall 122c and is an example of a “second sidewall.” The fixing members 300d and 300f are connected to the outer wall 122d. Furthermore, the fixing members 300a and 300b are connected to outer walls 142c and 142d (two sidewalls) of the head portion 140, respectively, which are described later with reference to FIG. 2.

The semiconductor module 200 is positioned between the bottom surface BF of the casing 400 and the outer surface OFa of the cooler 100, and is pressed by the bottom surface BF and the outer surface OFa due to fixing of the cooler 100 to the bottom surface BF with the fixing members 300. In this embodiment, this enables the semiconductor module 200 to be stably fixed to the cooler 100.

Since the semiconductor module 200 is stably fixed to the cooler 100 by the fixing members 300 that fix the cooler 100 to the casing 400 in this embodiment, no member for fixing the semiconductor module 200 to the cooler 100 is needed in addition to the fixing members 300. That is, in this embodiment, the semiconductor module 200 can be stably fixed to the cooler 100, and increase in the number of parts of the power converter 10 is suppressed.

The connection method of the fixing members 300 to the cooler 100, and the connection method of the fixing members 300 to the bottom surface

BF are not limited thereto. The connection between the fixing members 300 and the cooler 100 (the connection between the fixing members 300c and 300e and the outer wall 122c, and the like) may be implemented by adhesion with adhesive, by welding, or by screwing. Similarly, the connection between the fixing members 300 and the bottom surface BF may be implemented by adhesion with adhesive, by welding, or by screwing.

The cooler 100 cools the semiconductor module 200 arranged on the outer surface OFa of the outer wall 122a using the refrigerant flowing through the cooling flow paths FP3 having the inner surface IFa of the outer wall 122a as a part of the wall surfaces. In one example, heat generated in the semiconductor module 200 is released to the refrigerant via the outer wall 122a. Since the semiconductor module 200 is stably fixed to the cooler 100 in this embodiment, decrease in the cooling efficiency for the semiconductor module 200 is suppressed.

The main body 120 is made of a material high in thermal conductivity.

Specific constituent materials of the main body 120 include metals such as copper, aluminum, and alloys of any thereof. The head portion 140, the supply pipe 160, and the discharge pipe 162 are made of the same material as the main body 120. That is, specific constituent materials of the head portion 140, the supply pipe 160, and the discharge pipe 162 include metals such as copper, aluminum, and alloys of any thereof. One, some, or all of the head portion 140, the supply pipe 160, and the discharge pipe 162 may be made of a material different from the main body 120.

The shape of the main body 120 is not limited to the cuboid extending in the Y direction. The shape of the main body 120 in plan view from the −Y direction may be a shape having curved lines. That is, the outer walls 122c and 122d may be curved.

The casing 400 accommodates the cooler 100 and the semiconductor module 200. Although the material of the casing 400 is not limited thereto in this embodiment, a portion including the bottom surface BF is made of a material being highly thermally conductive.

The head portion 140 is explained next with reference to FIG. 2.

FIG. 2 is an explanatory diagram for the head portion 140 illustrated in FIG. 1. FIG. 2 includes a first plan view of the cooler 100 and the semiconductor module 200 as viewed from the −Z direction, and a second plan view of the cooler 100 and the semiconductor module 200 as viewed from the −Y direction. FIG. 2 further includes a cross-sectional view of the cooler 100 taken along line A1-A2 in the first plan view. In FIG. 2, illustrations of reference signs such as the input terminal 202u are omitted for simplicity. Illustrations of reference signs such as the input terminal 202u are appropriately omitted also in the drawings following FIG. 2.

The head portion 140 is a hollow cuboid having an opening communicated with the inflow path FP1, an opening communicated with the outflow path FP2, a supply port Hi, and a discharge port Ho.

The supply port Hi and the discharge port Ho are openings formed on an outer wall 142e substantially parallel to an X-Z plane as illustrated in the second plan view. The supply pipe 160 and the discharge pipe 162 are connected to the outer wall 142e. In one example, the supply pipe 160 is connected to the outer wall 142e in such a manner that the flow path in the supply pipe 160 is communicated with the supply port Hi. The discharge pipe 162 is connected to the outer wall 142e in such a manner that the flow path in the discharge pipe 162 is communicated with the discharge port Ho.

As illustrated in the A1-A2 cross-sectional view, the head portion 140 has outer walls 142a and 142b substantially parallel to an X-Y plane, outer walls 142c and 142d substantially parallel to a Y-Z plane, and outer walls 142f and 142g substantially parallel to the X-Z plane, as well as the outer wall 142e. The head portion 140 has a partition 144 substantially parallel to the Y-Z plane.

The outer walls 142f and 142g are arranged away from the outer wall 142e in the +Y direction and are connected to the outer walls 122c and 122d of the main body 120, respectively. The partition 144 separating a flow path from the supply port Hi to the inflow path FP1 and a flow path from the outflow path FP2 to the discharge port Ho from each other is arranged between the outer walls 122c and 122d of the main body 120 in the X direction. In one example, the partition 144 is connected to the following: (i) the outer walls 142a and 142b, (ii) a partition 124c closest to the head portion 140 among partitions 124c of the main body 120, which will be described later with reference to FIG. 3, (iii) a partition 124a of the main body 120, and (iv) a partition 124b of the main body 120, which will be described later with reference to FIG. 4.

The shape of the head portion 140 is not limited to that illustrated in FIG. 2. The shape of the head portion 140 in plan view from the −Y direction may be a shape having curved lines. That is, the outer walls 142c and 142d may be curved. In this case, the fixing members 300a and 300b respectively connected to the outer walls 142c and 142d may be removed. Alternatively, the fixing member 300a and the like may be connected to the outer wall 142e or the like, instead of the outer walls 142c and 142d.

The main body 120 is explained next with reference to FIGS. 3 and 4.

FIG. 3 is an explanatory diagram for the main body 120 illustrated in FIG. 1. FIG. 3 includes a plan view of the cooler 100 as viewed from the −Z direction. FIG. 3 further includes a cross-sectional view of the cooler 100 taken along line C1-C2 and a cross-sectional view of the cooler 100 taken along line D1-D2. Dashed arrows in FIG. 3 indicate the flow of the refrigerant.

In one example, the main body 120 has the partitions 124c arrayed in the Y direction as illustrated in the Cl-C2 cross-sectional view and the D1-D2 cross-sectional view. Each of the partitions 124c extends in the X direction. Two of the cooling flow paths FP3 adjacent to each other are separated from each other by a partition 124c located between the two cooling flow paths FP3.

The number of the partitions 124c is not limited to being multiple. One partition 124c may be provided when the number of the cooling flow paths FP3 is two. The cooling flow paths FP3 are positioned between the inflow path FP1 and the outflow path FP2, and the outer wall 122a in the Z direction perpendicular to the outer surface OFa. Each of the cooling flow paths FP3 causes the inflow path FP1 and the outflow path FP2 to be communicated with each other in the X direction.

In one example, the refrigerant having flowed from the supply pipe 160 into the inflow path FP1 flows in any of the cooling flow paths FP3. Heat exchange is performed between the refrigerant having flowed into the cooling flow paths FP3 and the semiconductor module 200. The refrigerant having flowed into the cooling flow paths FP3 flows in the outflow path FP2. The refrigerant having flowed into the outflow path FP2 is discharged from the discharge pipe 162. Thus, in this embodiment, the semiconductor module 200 is cooled by fresh refrigerant flowing from the inflow path FP1 into the cooling flow paths FP3. The fresh refrigerant is a refrigerant before the heat exchange with the semiconductor module 200, or it is a refrigerant at almost the same temperature as that of the refrigerant before the heat exchange with the semiconductor module 200.

In this embodiment, the partitions 124c are formed integrally with the outer wall 122a, as illustrated in the C1-C2 cross-sectional view and the D1-D2 cross-sectional view. In one example, the contact area between a structure in which the outer wall 122a and the partitions 124c are formed integrally with each other and the refrigerant is larger than the contact area between the outer wall 122a and the refrigerant in a case in which the partitions 124c are not connected to the outer wall 122a. Therefore, in this embodiment, the efficiency of heat transfer is improved in a case in which heat is transferred from the semiconductor module 200 to the refrigerant via the outer wall 122a.

In FIG. 3, a portion of the outer wall 122e formed integrally with the outer wall 122a is referred to as “outer wall 122ea” and a portion of the outer wall 122e other than the outer wall 122ea is referred to as “outer wall 122eb.”

A manufacturing method of elements such as the partitions 124c is not limited thereto. The partitions 124c formed integrally with the outer wall 122a may be or may not be connected to the partition 124a. The partitions 124c may not be formed integrally with the outer wall 122a, and instead may be formed integrally with the partition 124a. The partitions 124c formed integrally with the partition 124a may be or may not be connected to the outer wall 122a. Alternatively, the partitions 124c formed separately from the outer wall 122a and the partition 124a may be connected to one or both of the outer wall 122a and the partition 124a.

FIG. 4 is a cross-sectional view of the power converter 10 taken along line B1-B2 illustrated in the first plan view of FIG. 2. Illustrations of terminals such as the input terminals 202 of the semiconductor module 200 are omitted in FIG. 4 to simplify the drawing. Illustrations of elements such as a switching element included in the semiconductor module 200 are omitted in the cross-sectional view of the semiconductor module 200. Illustrations of the elements such as the switching element included in the semiconductor module 200 are also omitted in cross-sectional views of the semiconductor module 200 illustrated in the drawings following FIG. 4. A dashed arrow in FIG. 4 indicates flow of the refrigerant.

The power converter 10 has connecting members 500 and 502 in addition to the semiconductor module 200, the cooler 100, the fixing members 300, and the casing 400 illustrated in FIG. 1. Any thermal conductive material can be adopted as the connecting members 500 and 502. Examples of the thermal conductive material include Thermal Interface Material (TIM) such as thermal conductive grease, thermal conductive adhesive, thermal conductive sheet, and solder. In this embodiment, the connecting members 500 and 502 are solder.

The connecting member 500 is positioned between the outer surface OFa of the cooler 100 and the surface PF1 of the semiconductor module 200, and connects the outer surface OFa of the cooler 100 to the surface PF1 of the semiconductor module 200. The connecting member 502 is positioned between the bottom surface BF of the casing 400 and the surface PF2 of the semiconductor module 200, and connects the bottom surface BF of the casing 400 to the surface PF2 of the semiconductor module 200. Accordingly, heat of the semiconductor module 200 is efficiently transferred to the refrigerant in the cooler 100 via the connecting member 500, and is efficiently transferred to the casing 400 via the connecting member 502. As a result, in this embodiment, the semiconductor module 200 is efficiently cooled.

One or both of the connecting members 500 and 502 may be removed. The surface PF1 of the semiconductor module 200 may be physically in direct contact with the outer surface OFa of the cooler 100 without the connecting member 500 interposed therebetween. The surface PF2 of the semiconductor module 200 may be physically in contact with the bottom surface BF of the casing 400 without the connecting member 502 interposed therebetween. Hereinafter, the following (i) and (ii) are referred to as “being thermally connected”: (i) two elements being connected to each other via a thermal conductive material such as the connecting members 500 and 502, and (ii) two elements being physically in contact with each other with no thermal conductive material interposed therebetween.

The main body 120 has the partitions 124a and 124b in addition to the outer walls 122a, 122b, 122c, 122d, and 122e and the partitions 124c explained with reference to FIGS. 1 and 3.

The partition 124a is arranged to be spaced from the outer wall 122a in the +Z direction. That is, the partition 124a is arranged between the outer walls 122a and 122b.

In this embodiment, the partition 124a is substantially parallel to the outer wall 122a. In one example, a surface SFa1 directed to the inner surface IFa of the outer wall 122a among the surfaces of the partition 124a is substantially parallel to the inner surface IFa of the outer wall 122a. The surface SFa1 of the partition 124a may not be parallel to the inner surface IFa of the outer wall 122a. The surface SFa1 of the partition 124a may be inclined in such a manner that an edge of the surface SFa1 in the −X direction is more distant from the outer wall 122a.

The partition 124a arranged between the outer walls 122a and 122b separates the inflow path FP1 from the cooling flow paths FP3, and separates the outflow path FP2 from the cooling flow paths FP3. A space enabling the inflow path FP1 to be communicated with the cooling flow paths FP3 is provided between the edge of the partition 124a in the −X direction and an inner surface IFc of the outer wall 122c. Similarly, a space enabling the outflow path FP2 to be communicated with the cooling flow paths FP3 is provided between an edge of the partition 124a in the +X direction and an inner surface IFd of the outer wall 122d. That is, in this embodiment, each of the cooling flow paths FP3 is communicated with the inflow path FP1 at one end, and is communicated with the outflow path FP2 at the other end.

The partition 124b is arranged between the outer walls 122c and 122d and is connected to the partition 124a and the outer wall 122b. In one example, a surface SFb1 of the partition 124b is directed to the inner surface IFc of the outer wall 122c among the surfaces of the partition 124b, and is substantially parallel to the inner surface IFc of the outer wall 122c. A surface SFb2 of the partition 124b is directed to the inner surface IFd of the outer wall 122d among the surfaces of the partition 124b, and is substantially parallel to the inner surface IFd of the outer wall 122d.

The partition 124b arranged between the outer walls 122c and 122d separates the inflow path FP1 and the outflow path FP2 from each other. In one example, a surface SFa2 of the partition 124a, the surface SFb1 of the partition 124b, and an inner surface IFb1 of the outer wall 122b are a part of the wall surface of the inflow path FP1. A surface SFa3 of the partition 124a, a surface SFb2 of the partition 124b, and an inner surface IFb2 of the outer wall 122b are parts of the wall surface of the outflow path FP2. The surface SFa2 of the partition 124a is a portion of the opposite surface to the surface SFa1, which is located in the −X direction relative to the partition 124b, and the surface SFa3 of the partition 124a are portions of the opposite surface to the surface SFa1, which is located in the +X direction relative to the partition 124b. The inner surface IFb1 of the outer wall 122b is a portion of an inner surface IFb of the outer wall 122b, which is located in the −X direction relative to the partition 124b, and the inner surface IFb2 of the outer wall 122b is a portion of the inner surface IFb of the outer wall 122b, which is located in the +X direction relative to the partition 124b.

The partitions 124c are walls substantially perpendicular to the outer wall 122a and extend in the X direction. For example, the partitions 124c are arranged between the partition 124a and the outer wall 122a and are connected to the outer walls 122a, 122c, and 122d and the partition 124a. That is, in this embodiment, the partitions 124c are connected to both the partition 124a and the outer wall 122a. The partitions 124c may be connected to only one of the partition 124a and the outer wall 122a. Each of the cooling flow paths FP3 is formed, for example, between ones of the partitions 124c adjacent to each other. The inner surface IFa of the outer wall 122a and the surface SFa1 of the partition 124a are a part of the wall surfaces of the cooling flow paths FP3.

In this embodiment, the surface PF1 of the semiconductor module 200 is connected to the outer surface OFa of the outer wall 122a including the inner surface IFa being a part of the wall surfaces of the cooling flow paths FP3, via the connecting member 500.

In one example, in this embodiment, the cooler 100 is fixed to the casing 400 by connecting the outer walls 122c and 122d to the bottom surface BF of the casing 400 with the fixing members 300 in a state in which the semiconductor module 200 is sandwiched between the outer surface OFa and the bottom surface BF of the casing 400. Accordingly, the surface PF1 of the semiconductor module 200 is pressed by the outer surface OFa of the cooler 100 with a force F while the surface PF2 of the semiconductor module 200 on the opposite side to the surface PF1 is pressed by the bottom surface BF of the casing 400 with the force F. That is, the semiconductor module 200 is pressed by the outer surface OFa of the cooler 100 and the bottom surface BF of the casing 400, with the force F from both the +Z direction and the −Z direction, respectively.

As a result, the semiconductor module 200 is stably fixed between the outer surface OFa of the cooler 100 and the bottom surface BF of the casing 400. Accordingly, in this embodiment, it is possible to suppress decrease of (i) the thermal conductivity between the semiconductor module 200 and the outer surface OFa of the cooler 100 and (ii) the thermal conductivity between the semiconductor module 200 and the bottom surface BF of the casing 400. That is, in this embodiment, the semiconductor module 200 is efficiently cooled.

Since the semiconductor module 200 is pressed from both sides by the outer surface OFa of the cooler 100 and the bottom surface BF of the casing 400 in this embodiment, displacement of the semiconductor module 200 from a predetermined location due to vibration or the like of the power converter 10 can be suppressed. Thus, this embodiment can improve the reliability of the power converter 10 by stably fixing the semiconductor module 200 between the outer surface OFa of the cooler 100 and the bottom surface BF of the casing 400.

Since the cooling flow paths FP3 are positioned between the inflow path FP1 and the outflow path FP2, and the outer wall 122a in the Z direction in this embodiment, a space is provided in the Z direction of terminals (such as the input terminals 202 and 204 and the output terminal 206) of the semiconductor module 200. In one example, the inflow path FP1 and the outflow path FP2 are positioned in the +Z direction relative to the partitions 124c separating the cooling flow paths FP3. Accordingly, in this embodiment, the inner surface IFc of the outer wall 122c defining one end of each of the cooling flow paths FP3 can be a part of the wall surface of the inflow path FP1. Additionally, the inner surface IFd of the outer wall 122d defining the other end of each of the cooling flow paths FP3 can be a part of the wall surface of the outflow path FP2. In this case, a space is provided in the Z direction of the terminals of the semiconductor module 200, and therefore lines and other similar parts are connected to the terminals of the semiconductor module 200 with ease.

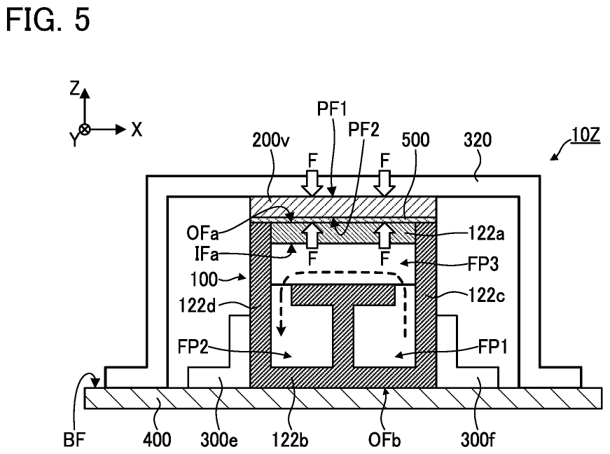

A mode (hereinafter, also referred to as “comparative example”) in which the cooler 100 is positioned between the semiconductor module 200 and the bottom surface BF of the casing 400 is explained next as a mode to be compared with the power converter 10, with reference to FIG. 5.

FIG. 5 is an explanatory diagram for an example of a power converter 10Z according to the comparative example. In FIG. 5, a cross-sectional view of the power converter 10Z, which corresponds to the cross-sectional view of the power converter 10 illustrated in FIG. 4, is illustrated. To simplify the drawing, illustrations of the terminals such as the input terminal 202 of the semiconductor module 200 are omitted also in FIG. 5. Elements substantially the same as the elements described in FIGS. 1 to 4 are denoted by like reference signs, and detailed explanations thereof are omitted. Dashed arrows in the drawing indicate the flow of the refrigerant.

The power converter 10Z is substantially the same as the power converter 10 illustrated in FIG. 4 and the like except for having a module fixing member 320, and for the positional relationships among the cooler 100, the semiconductor module 200, and the bottom surface BF of the casing 400. In one example, the cooler 100 is positioned between the semiconductor module 200 and the bottom surface BF of the casing 400. Accordingly, the cooler 100 is connected to the bottom surface BF of the casing 400 with the fixing members 300 in such a manner that the cooling flow paths FP3 are positioned in the +Z direction relative to the inflow path FP1 and the outflow path FP2.

The semiconductor module 200 is arranged on the outer surface OFa of the cooler 100 in such a manner that the surface PF2 is directed to the outer surface OFa of the cooler 100. The connecting member 500 is interposed between the surface PF2 of the semiconductor module 200 and the outer surface OFa of the cooler 100. The module fixing member 320 is fixed to the bottom surface BF of the casing 400 so as to press the surface PF2 of the semiconductor module 200 on the opposite side to the surface PF1 in the —Z direction. Accordingly, the semiconductor module 200 is pressed by the outer surface OFa of the cooler 100 and the module fixing member 320 with a force F from both the +Z direction and the −Z direction, respectively.

Thus, the module fixing member 320 is used in addition to the fixing members 300 to stably fix the semiconductor module 200 to the cooler 100 in the power converter 10Z of the comparative example. That is, in the comparative example, the number of parts of the power converter 10Z is increased as compared to the power converter 10 according to this embodiment. Removing the module fixing member 320 in the comparative example causes unstable connection between the semiconductor module 200 and the cooler 100, and thus, the reliability of the power converter 10Z is reduced. Vibration of the power converter 10Z might cause the semiconductor module 200 to detach from the cooler 100 or to fall off the cooler 100. The detachment of the semiconductor module 200 from the cooler 100 results in decrease in the cooling efficiency for the semiconductor module 200. The fall of the semiconductor module 200 off the cooler 100 might cause fault in the power converter 10Z.

In contrast thereto, the semiconductor module 200 can be stably fixed to the cooler 100 in this embodiment, without installing a member (for example, the module fixing member 320) that fixes the semiconductor module 200 to the cooler 100 in addition to the fixing members 300. That is, the reliability of the power converter 10 is improved in this embodiment while the number of parts of the power converter 10 is suppressed from increasing.

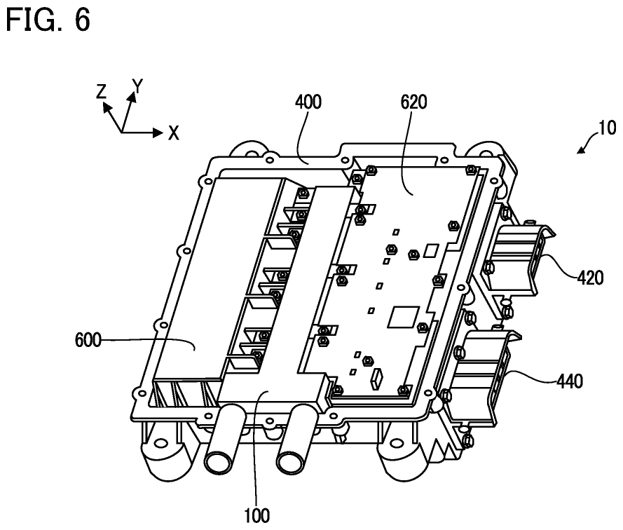

A schematic internal structure of the entire power converter 10 is explained next with reference to FIG. 6.

FIG. 6 is a perspective view illustrating an example of a schematic internal structure of the entire power converter 10.

The power converter 10 has a capacitor 600, a control substrate 620, an input connector 420, an output connector 440, and the like, in addition to the semiconductor module 200, the cooler 100, the fixing members 300, the casing 400, the connecting members 500 and 502 illustrated in FIG. 4 and other drawings. The capacitor 600 smooths a DC voltage applied between the input terminals 202 and 204 of the semiconductor module 200. A control circuit that controls the semiconductor module 200, and the other parts are installed on the control substrate 620. The casing 400 accommodates inner parts of the power converter 10, such as the cooler 100, the semiconductor module 200, the capacitor 600, and the control substrate 620. The casing 400 is provided with the input connector 420 and the output connector 440. In one example, a DC voltage is applied between the input terminals 202 and 204 of the semiconductor module 200 from a DC power source (not illustrated) via the input connector 420. AC power of three phases including a U phase, a V phase, and a W phase is output from the output terminal 206 of the semiconductor module 200 to an external device (not illustrated; for example, a motor) via the output connector 440.

The configuration of the power converter 10 is not limited to the example illustrated in FIG. 6. Since the cooler 100 cools the semiconductor module 200 from the surface PF1 that is one of the surfaces PF1 and PF2 in this embodiment, the size of the cooler 100 in the Z direction is decreased. Therefore, in this embodiment, a space for arranging other members is allocated in the +Z direction of the semiconductor module 200. In one example, the control substrate 620 may be arranged in such a manner that a part thereof overlaps the cooler 100 in plan view from the +Z direction. In this case, the size of the power converter 10 in the X direction is decreased, while increase in the size of the power converter 10 in the Z direction is suppressed.

In the foregoing embodiment, the power converter 10 has the semiconductor module 200, the cooler 100 including the flow paths through which a refrigerant flows, the casing 400 including the bottom surface BF, and the fixing members 300c, 300d, 300e, and 300f that fix the cooler 100 to the bottom surface BF. The cooler 100 includes the outer surface OFa directed to the bottom surface BF of the casing 400, and the inner surface IFa constituting a part of the wall surfaces of flow paths (for example, the cooling flow paths FP3) on the opposite side to the outer surface OFa. The cooler 100 further includes the outer wall 122c to which the fixing members 300c and 300e are connected, and the outer wall 122d that is a sidewall on the opposite side to the outer wall 122c and to which the fixing members 300d and 300f are connected. The semiconductor module 200 is positioned between the bottom surface BF of the casing 400 and the outer surface OFa of the cooler 100, and is pressed by the bottom surface BF of the casing 400 and the outer surface OFa of the cooler 100.

Thus, in this embodiment, the semiconductor module 200 is pressed from both sides by the bottom surface BF of the casing 400 and the outer surface OFa of the cooler 100, and therefore, the semiconductor module 200 is stably fixed to the cooler 100. As a result, in this embodiment, the semiconductor module 200 is efficiently cooled. Furthermore, in this embodiment, the fixing members 300 fix the cooler 100 to the casing 400 and also stably fix the semiconductor module 200 to the cooler 100. Therefore, in this embodiment, any member for fixing the semiconductor module 200 to the cooler 100 is no longer need in addition to the fixing members 300. Consequently, the number of parts of the power converter 10 can be reduced in this embodiment while decrease in the reliability of the power converter 10 is suppressed.

In this embodiment, the semiconductor module 200 is connected to the outer surface OFa of the cooler 100 by the connecting member 500. The connecting member 500 is a thermal conductive material. In one example, the connecting member 500 is solder. Thus, since the semiconductor module 200 is connected to the outer surface OFa of the cooler 100 by the connecting member 500 being a thermal conductive material such as solder in this embodiment, heat of the semiconductor module 200 is efficiently transferred to the refrigerant in the cooler 100. As a result, in this embodiment, the semiconductor module 200 is efficiently cooled.

In this embodiment, the semiconductor module 200 is connected to the bottom surface FB of the casing 400 by the connecting member 502. The connecting member 502 is a thermal conductive material. In one example, the connecting member 502 is solder. Thus, since the semiconductor module 200 is connected to the bottom surface BF of the casing 400 by the connecting member 502 being a thermal conductive material such as solder in this embodiment, heat of the semiconductor module 200 is efficiently transferred to the casing 400.

In this embodiment, the flow paths include the inflow path FP1 that extends in the Y direction and that has an end into which the refrigerant flows, the outflow path FP2 that extends in the Y direction and that has an end from which the refrigerant flows, and the cooling flow paths FP3 having the inner surface IFa of the cooler 100 as a part of the wall surface. The cooling flow paths FP3 are arrayed in the Y direction and extend in the X direction intersecting with the Y direction. The cooling flow paths FP3 are positioned between the inflow path FP1 and the outflow path FP2, and the outer surface OFa in the Z direction perpendicular to the outer surface OFa of the cooler 100. Each of the cooling flow paths FP3 causes the inflow path FP1 and the outflow path FP2 to be communicated with each other in the X direction.

Thus, in this embodiment, heat exchange is performed between the refrigerant in the cooling flow paths FP3 positioned between the inflow path FP1 and the outflow path FP2, and the outer surface OFa in the Z direction, and the semiconductor module 200. Therefore, in this embodiment, the inflow path FP1, the outflow path FP2, and the cooling flow paths FP3 can be formed while a space is provided in the Z direction of the terminals (such as the input terminals 202 and 204, and the output terminal 206) of the semiconductor module 200. As a result, in this embodiment, lines and the similar parts can be easily connected to the terminals of the semiconductor module 200.

### B: Modifications

The embodiments illustrated above can be variously modified. Specific aspects of modifications that can be applied to the embodiments described above are illustrated below. Two or more of the aspects freely selected from the following exemplifications may be appropriately combined so long as they do not conflict.

### B1: First Modification

In the foregoing embodiment, an electronic part different from the semiconductor module 200 may be thermally connected to an outer wall 122 (for example, the outer wall 122b) among the outer walls 122 of the cooler 100 other than the outer wall 122a thermally connected to the semiconductor module 200.

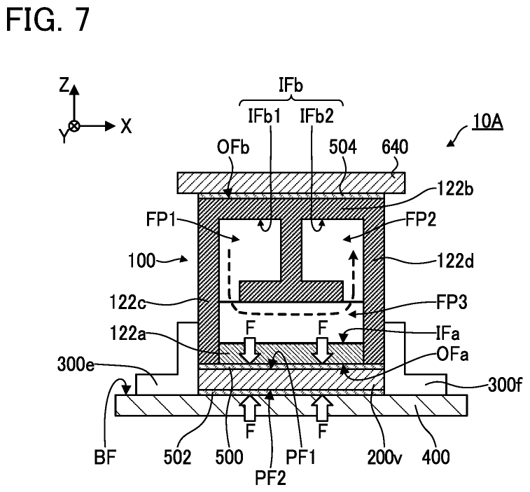

FIG. 7 is an explanatory diagram for an example of a power converter 10A according to a first modification. In FIG. 7, a cross-sectional view of the power converter 10A, which corresponds to the cross-sectional view of the power converter 10 illustrated in FIG. 4, is illustrated. Furthermore, illustrations of the terminals such as the input terminal 202 of the semiconductor module 200 are omitted to simplify FIG. 7. Elements substantially the same as the elements described in FIGS. 1 to 6 are denoted by like reference signs and detailed explanations thereof are omitted. Dashed arrows in the drawing indicate an example of the flow of refrigerant.

The power converter 10A is substantially the same as the power converter 10 illustrated in FIG. 4 and the like except for further having an electronic part 640 arranged on the cooler 100. In one example, the electronic part 640 is arranged on the outer surface OFb of the outer wall 122b included in the cooler 100 with a connecting member 504 interposed therebetween. The cooler 100 is positioned between the electronic part 640 and the semiconductor module 200.

That is, in this modification, the electronic part 640 is thermally connected to the outer surface OFb of the cooler 100. The semiconductor module 200 is thermally connected to the outer surface OFa of the cooler 100. Any thermal conductive material can be adopted as the connecting member 504 similarly to the connecting member 500. In this modification, the connecting member 504 is a TIM other than solder in view of the assembly procedure of the power converter 10A. In this case, execution of a heating process after fixing of the cooler 100 to the casing 400 is avoided.

Thus, the electronic part 640 is connected to the outer surface OFb of the outer wall 122b via the connecting member 504 in this modification. The outer wall 122b includes (i) the inner surface IFb1 that is a part of the wall surface of the inflow path FP1, and (ii) the inner surface IFb2 that is a part of the wall surface of the outflow path FP2. Accordingly, heat of the electronic part 640 is transferred to the refrigerant in the inflow path FP1 and the refrigerant in the outflow path FP2 in this modification. That is, parts including the semiconductor module 200 and the electronic part 640 are cooled by one cooler 100 in this modification.

The type of the electronic part 640 is not limited thereto. The electronic part 640 may be a portion of the control substrate 620 illustrated in FIG. 6. Alternatively, the electronic part 640 may be a thermally conductive member, such as a sheet of metal. The thermally conductive member is connected to a heat generator, such as the capacitor 600 illustrated in FIG. 6, and dissipates heat of the heat generator.

The configuration of the power converter 10A is not limited to the example illustrated in FIG. 7. The electronic part 640 may be pressed from the +Z direction.

This modification achieves effects substantially the same as those of the embodiments described above. The power converter 10A further has the electronic part 640 arranged on the cooler 100 in this modification. The cooler 100 is positioned between the electronic part 640 and the semiconductor module 200. Therefore, both the semiconductor module 200 and the electronic part 640 can be cooled by the cooler 100 positioned between the semiconductor module 200 and the electronic part 640 in this modification. That is, in this modification, parts including the semiconductor module 200 and the electronic part 640 are cooled by the cooler 100 while increase in the number of parts is suppressed.

### B2: Second Modification

Although the cooler 100 in which the supply pipe 160 and the discharge pipe 162 are installed on the same head portion 140 is illustrated in the embodiment and the modification, the present invention is not limited to such a mode. For example, the supply pipe 160 and the discharge pipe 162 may be respectively installed on two different head portions 140.

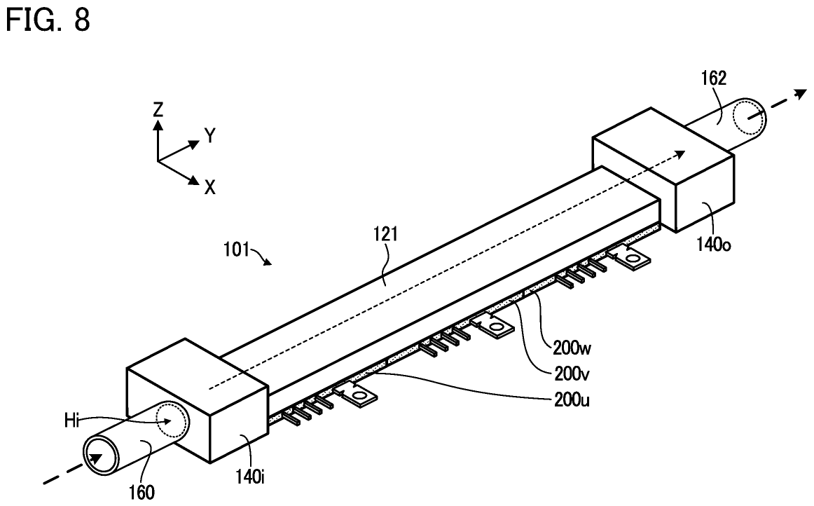

FIG. 8 is an explanatory diagram for an example of a cooler 101 according to a second modification. A perspective view of the cooler 101 is illustrated in FIG. 8. Dashed arrows in the drawing indicate the flow of the refrigerant. Elements substantially the same as the elements described in FIGS. 1 to 7 are denoted by like reference signs, and detailed explanations thereof are omitted.

The cooler 101 has a main body 121 extending in the Y direction, the supply pipe 160, the discharge pipe 162, a head portion 140i that connects the supply pipe 160 to the main body 121, and a head portion 140o that connects the discharge pipe 162 to the main body 121. The main body 121 includes at least one flow path extending in the Y direction. At least one flow path formed in the main body 121 allow the refrigerant flowing therein from the supply pipe 160 via the head portion 140i to flow in the discharge pipe 162 via the head portion 140o.

In this modification, the cooler 101 is fixed to the bottom surface BF of the casing 400 (not illustrated in FIG. 8) by the fixing members 300 in a state in which the semiconductor module 200 is sandwiched between the cooler 101 and the bottom surface BF of the casing 400, similarly to the cooler 100 illustrated in FIG. 1 and other drawings. This modification also achieves effects substantially the same as those of the embodiments described above.

### B3: Third Modification

In the embodiment, a case is given in which fixing members 300 are connected to the respective side surfaces of the outer wall 122c. Other fixing members 300 are connected to the respective side surfaces of the outer wall 122d. However, the present invention is not limited to such a mode. The bottom surface (a surface directed to the bottom surface BF of the casing 400) of the outer wall 122c and the bottom surface BF of the casing 400 may be screwed together. The bottom surface of the outer wall 122d and the bottom surface BF may be screwed together. Specifically, a screw hole may be formed on the bottom surface of each of the outer walls 122c and 122d, and openings may be formed on portions respectively corresponding to the screw holes of the outer walls 122c and 122d in a part including the bottom surface BF of the casing 400. The cooler 100 may be fixed to the bottom surface BF of the casing 400 by screwing with screws penetrating through the through holes and the screw holes, respectively. In this case, the screw corresponding to the screw hole of the outer wall 122c is another example of the “first fixing member,” and the screw corresponding to the screw hole of the outer wall 122d is another example of the “second fixing member.” This modification also can achieve effects substantially the same as those of the embodiments described above.

### B4: Fourth Modification

Although a case is given in which the power converter 10 has the casing 400 that accommodates the semiconductor module 200 and the cooler 100 in the embodiment, the present invention is not limited to such a mode. The power converter 10 may have a support plate including an installation surface on which the semiconductor module 200 and the cooler 100 are installed, instead of the casing 400. The support plate is, for example, a plate-shaped support that is made of a highly thermally conductive material. That is, a part or the entirety of the semiconductor module 200 and the cooler 100 may not be accommodated in the casing 400. This modification can achieve effects substantially the same as those of the embodiment.

### B5: Fifth Modification

Although the case is given in which each of the cooling flow paths FP3 is communicated with the inflow path FP1 at one end and is communicated with the outflow path FP2 at the other end in the embodiment, the present invention is not limited to such a mode. Each of the cooling flow paths FP3 may be communicated with the inflow path FP1 near an intermediate portion between the inner surface IFc of the outer wall 122c and the surface SFb1 of the partition 124b. Furthermore, each cooling flow path FP3 may be communicated with the outflow path FP2 near an intermediate portion between the inner surface IFd of the outer wall 122d and the surface

SFb2 of the partition 124b in the X direction. This modification can achieve effects substantially the same as those of the embodiments and the modifications described above.

### Description of Reference Signs

10, 10A, 10Z . . . power converter, 100, 101 . . . cooler, 120, 121 . . . main body, 122a, 122b, 122c, 122d, 122e, 122ea, 122eb, 142a, 142b, 142c, 142d, 142e, 142f, 142g . . . outer wall, 124a, 124b, 124c, 144 . . . partition, 140, 140i, 140o . . . head portion, 160 . . . supply pipe, 162 . . . discharge pipe, 200u, 200v, 200w . . . semiconductor module, 202u, 202v, 202w, 204u, 204v, 204w . . . input terminal, 206u, 206v, 206w . . . output terminal, 208u, 208v, 208w . . . control terminal, 300a, 300b, 300c, 300d, 300e, 300f . . . fixing member, 400 . . . casing, 420 . . . input connector, 440 . . . output connector, 500, 502, 504 . . . connecting member, 600 . . . capacitor, 620 . . . control substrate, 640 . . . electronic part, FP1 . . . inflow path, FP2 . . . outflow path, FP3 . . . cooling flow path, Hi . . . supply port, Ho . . . discharge port, BF . . . bottom surface, IFa, IFb, IFB1, IFb2, IFc, IFd . . . inner surface, OFa, OFb . . . outer surface, PF1, PF2, SFa1, SFa2, SFa3, SFb1, SFb2 . . . surface.

What is claimed is:

1. A semiconductor apparatus comprising:
a semiconductor module;
a cooler including flow paths through which a refrigerant flows;
a support including an installation surface;
at least one first fixing member fixing the cooler to the installation surface; and
at least one second fixing member fixing the cooler to the installation surface, wherein:
the cooler includes:
a first surface directed to the installation surface;
a second surface that is a part of wall surfaces of the flow paths on an opposite side to the first surface;
a first sidewall to which the at least one first fixing member is connected; and
a second sidewall that is on an opposite side to the first sidewall and to which the at least one second fixing member is connected, and
the semiconductor module is positioned between the installation surface and the first surface, and is pressed by the installation surface and the first surface.

2. The semiconductor apparatus according to claim 1,
wherein the semiconductor module is connected to the first surface with solder.

3. The semiconductor apparatus according to claim 1,
wherein the semiconductor module is connected to the first surface with a thermal conductive material.

4. The semiconductor apparatus according to claim 1,
wherein the semiconductor module is connected to the installation surface with solder.

5. The semiconductor apparatus according to claim 1,
wherein the semiconductor module is connected to the installation surface with a thermally conductive material.

6. The semiconductor apparatus according to claim 1, further comprising an electronic part arranged on the cooler,
wherein the cooler is positioned between the electronic part and the semiconductor module.

7. The semiconductor apparatus according to claim 1, wherein:
the flow paths include:
a first flow path extending in a first direction, and having an end into which the refrigerant to flows;
a second flow path extending in the first direction, and having an end from which the refrigerant flows out; and
a plurality of cooling flow paths having the second surface as a part of a wall surface,
the plurality of cooling flow paths are arrayed in the first direction, the plurality of cooling flow paths extend in a second direction intersecting with the first direction,
the plurality of cooling flow paths are positioned between the first and second flow paths and the first surface in a third direction perpendicular to the first surface, and
each of the plurality of cooling flow paths causes the first flow path and the second flow path to communicate with each other in the second direction.
